(19) United States
(12) Patent Application Publication
(10) Pub. No.: US 2022/0122837 A1
(43) Pub. Date: Apr. 21, 2022

(54) Approach for Fabricating N-Polar AlxGa1-xN Devices

(71) Applicant: University of South Carolina, Columbia, SC (US)

(72) Inventor: Asif Khan, Irmo, SC (US)

(73) Assignee: University of South Carolina, Columbia, SC (US)

(21) Appl. No.: 17/504,685

(22) Filed: Oct. 19, 2021

Related U.S. Application Data
(60) Provisional application No. 63/094,419, filed on Oct. 21, 2020.

(51) Int. Cl. H01L 21/02; H01L 21/78; H01L 29/66

(52) U.S. Cl. CPC H01L 21/0254; H01L 21/02458; H01L 21/7806; H01L 29/66462; H01L 21/02381; H01L 21/02496; H01L 21/0242

(57) ABSTRACT

A new approach for fabricating N-polar devices without the need of developing N-polar AlₓGa₁₋ₓN buffer layers over substrates such as sapphire, SiC, GaN, AlN and AlₓGa₁₋ₓN using a simplified material growth process.

### TECHNICAL FIELD

The subject matter disclosed herein is generally directed to a new approach for fabricating N-polar devices without the need of developing N-polar AlₓGa₁₋ₓN buffer layers over substrates such as sapphire, SiC, GaN, AlN and AlₓGa₁₋ₓN using a simplified material growth process.

### BACKGROUND

Microelectronic and microphotonic devices using AlₓGa₁₋ₓN materials can have either Al/Ga-polar or N-polar crystal orientations. These components are integral to power and rf-electronics and a basis for all electronics for electric cars. The Al/Ga polar orientations are easy to grow. However, growth of epitaxial layers for N-polar oriented devices is very difficult. This difficulty increases when the active layers have high Al-composition. However, in spite of difficult growth, the N-polar devices have many properties far superior to their A/Ga-polar counterparts. Accordingly, it is an object of the present disclosure to provide an approach for circumventing these growth difficulties.

Citation or identification of any document in this application is not an admission that such a document is available as prior art to the present disclosure.

### SUMMARY

The above objectives are accomplished according to the present disclosure by providing in one embodiment, an improved method for forming N-polar device layers. The method may include growing at least one N-polar stacked configuration in reverse order via: forming at least one N-polar epilayer over a UV transparent III-N epitaxy compatible substrate, forming at least one polar substrate, forming at least one layer of boron nitride adjacent the substrate, forming at least one heat sink as an uppermost layer of the stacked configuration, separating the substrate and removing the at least one layer of boron nitride adjacent the substrate; and inverting the stacked configuration to configure the at least one heat sink as a substrate carrier. Further, the at least one polar substrate includes Ga or Al. Still, the UV transparent III-N epitaxy compatible substrate may be sapphire. Further, the UV transparent III-N epitaxy compatible substrate may be silicon. Furthermore, from 2-10 layers of boron nitride may be formed adjacent the substrate. Still yet, the method may form an N-polar epilayer stack as shown in FIG. 6. Again, at least one GaN layer may be formed between the substrate and heat sink. Further again, at least one AlxGxN layer may be formed between the substrate and heat sink. Yet further, at least one AlxInxN layer may be placed between the substrate and heat sink to serve as an etch stop marker. Still further, a second boron nitride layer may be placed between the substrate and heat sink. Yet again, the method may include removing the second boron nitride layer. Moreover, separating the substrate and removing the at least one layer of boron nitride adjacent the substrate may expose an N-polar face of the stack configuration. Further again, the method may include etching a GaN layer to reveal a GaN cap layer. Yet furthermore, the method may include fabricating a GaN—AlGaN high electron mobility transistor from the configuration stack.

A further embodiment provides an improved method for forming N-polar device layers. This method may include growing at least one N-polar device in reverse order via forming at least one N-polar device epilayer over a UV transparent III-N epitaxy compatible substrate, forming at least one layer of boron nitride adjacent the substrate, forming at least one AlN or GaN buffer layer adjacent the at least one layer of boron nitride, forming at least one heat sink as an uppermost layer to create a stacked configuration, forming at least one GaN layer between the substrate and heat sink, separating the substrate and removing the at least one layer of boron nitride adjacent the substrate, and inverting the stacked configuration to configure the at least one heat sink as a substrate carrier. Still, the method may include an N-polar epilayer stack as shown in FIG. 6. Yet again, the method may include forming at least one AlxGxN layer between the substrate and heat sink. Further yet, at least one AlxInxN layer may be formed between the substrate and heat sink to serve as an etch stop marker. Furthermore, the method may include wherein separating the substrate and removing the at least one layer of boron nitride adjacent the substrate exposes an N-polar face of the stack configuration.

These and other aspects, objects, features, and advantages of the example embodiments will become apparent to those having ordinary skill in the art upon consideration of the following detailed description of example embodiments.

### BRIEF DESCRIPTION OF THE DRAWINGS

An understanding of the features and advantages of the present disclosure will be obtained by reference to the following detailed description that sets forth illustrative embodiments, in which the principles of the disclosure may be utilized, and the accompanying drawings of which:

FIG. 1 shows a multilayer structure of the current disclosure.

FIG. 2 shows mounting a heat sink for laser liftoff.

FIG. 3 shows laser liftoff and structure inversion.

FIG. 4 shows a metal heat sink assembly that acts as a substrate carrier for the epilayers.

FIG. 5 shows ICPRIE or Tape separation.

FIG. 6 shows a final N-polar epilayer stack that can now be used to fabricate the GaN—AlGaN HEMT.

FIG. 7 shows regrown contacts and gate recess with a SiO₂ gate insulator for a final device.

FIG. 8 shows at: (a) The device structure of the AlGaN/GaN HEMT, Optical images of the HEMT (b) before and, (c) after laser lift-off.

FIG. 9 shows frequency dependent C-V characteristics of the AlGaN/GaN HEMT: (a) before and, (b) after laser lift-off. Inset figures show the gate leakage characteristics.

FIG. 10 shows at: (a) Raman spectra E2 (high) and A1 (LO) peaks of the GaN/AlGaN HEMT before and after the laser lift-off process showing redshift of 2.42 cm-1, Raman strain mapping of E2 phonon frequency for the access region of (b) as-fabricated, and (c) laser lifted-off HEMT

FIG. 11 shows LLO transfer of an AlN heat spreader onto commercial submount packaging.

FIG. 12 shows an example of 1 mm blocks that have been transferred from the sapphire, and the characterization of their optoelectronic integrity using cathodoluminescence.

The figures herein are for illustrative purposes only and are not necessarily drawn to scale.

### DETAILED DESCRIPTION OF THE EXAMPLE EMBODIMENTS

Before the present disclosure is described in greater detail, it is to be understood that this disclosure is not limited to particular embodiments described, and as such may, of course, vary. It is also to be understood that the terminology used herein is for the purpose of describing particular embodiments only, and is not intended to be limiting.

Unless specifically stated, terms and phrases used in this document, and variations thereof, unless otherwise expressly stated, should be construed as open ended as opposed to limiting. Likewise, a group of items linked with the conjunction “and” should not be read as requiring that each and every one of those items be present in the grouping, but rather should be read as “and/or” unless expressly stated otherwise. Similarly, a group of items linked with the conjunction “or” should not be read as requiring mutual exclusivity among that group, but rather should also be read as “and/or” unless expressly stated otherwise.

Furthermore, although items, elements or components of the disclosure may be described or claimed in the singular, the plural is contemplated to be within the scope thereof unless limitation to the singular is explicitly stated. The presence of broadening words and phrases such as “one or more,” “at least,” “but not limited to” or other like phrases in some instances shall not be read to mean that the narrower case is intended or required in instances where such broadening phrases may be absent.

Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, the preferred methods and materials are now described.

All publications and patents cited in this specification are cited to disclose and describe the methods and/or materials in connection with which the publications are cited. All such publications and patents are herein incorporated by references as if each individual publication or patent were specifically and individually indicated to be incorporated by reference. Such incorporation by reference is expressly limited to the methods and/or materials described in the cited publications and patents and does not extend to any lexicographical definitions from the cited publications and patents. Any lexicographical definition in the publications and patents cited that is not also expressly repeated in the instant application should not be treated as such and should not be read as defining any terms appearing in the accompanying claims. The citation of any publication is for its disclosure prior to the filing date and should not be construed as an admission that the present disclosure is not entitled to antedate such publication by virtue of prior disclosure. Further, the dates of publication provided could be different from the actual publication dates that may need to be independently confirmed.

As will be apparent to those of skill in the art upon reading this disclosure, each of the individual embodiments described and illustrated herein has discrete components and features which may be readily separated from or combined with the features of any of the other several embodiments without departing from the scope or spirit of the present disclosure. Any recited method can be carried out in the order of events recited or in any other order that is logically possible.

Where a range is expressed, a further embodiment includes from the one particular value and/or to the other particular value. The recitation of numerical ranges by endpoints includes all numbers and fractions subsumed within the respective ranges, as well as the recited endpoints. Where a range of values is provided, it is understood that each intervening value, to the tenth of the unit of the lower limit unless the context clearly dictates otherwise, between the upper and lower limit of that range and any other stated or intervening value in that stated range, is encompassed within the disclosure. The upper and lower limits of these smaller ranges may independently be included in the smaller ranges and are also encompassed within the disclosure, subject to any specifically excluded limit in the stated range. Where the stated range includes one or both of the limits, ranges excluding either or both of those included limits are also included in the disclosure. For example, where the stated range includes one or both of the limits, ranges excluding either or both of those included limits are also included in the disclosure, e.g. the phrase “x to y” includes the range from ‘x’ to ‘y’ as well as the range greater than ‘x’ and less than ‘y’. The range can also be expressed as an upper limit, e.g. ‘about x, y, z, or less’ and should be interpreted to include the specific ranges of ‘about x’, ‘about y’, and ‘about z’ as well as the ranges of ‘less than x’, less than y′, and ‘less than z’. Likewise, the phrase ‘about x, y, z, or greater’ should be interpreted to include the specific ranges of ‘about x’, ‘about y’, and ‘about z’ as well as the ranges of ‘greater than x’, greater than y′, and ‘greater than z’. In addition, the phrase “about ‘x’ to ‘y’”, where ‘x’ and ‘y’ are numerical values, includes “about ‘x’ to about ‘y’”.

It should be noted that ratios, concentrations, amounts, and other numerical data can be expressed herein in a range format. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. Ranges can be expressed herein as from “about” one particular value, and/or to “about” another particular value. Similarly, when values are expressed as approximations, by use of the antecedent “about,” it will be understood that the particular value forms a further aspect. For example, if the value “about 10” is disclosed, then “10” is also disclosed.

It is to be understood that such a range format is used for convenience and brevity, and thus, should be interpreted in a flexible manner to include not only the numerical values explicitly recited as the limits of the range, but also to include all the individual numerical values or sub-ranges encompassed within that range as if each numerical value and sub-range is explicitly recited. To illustrate, a numerical range of “about 0.1% to 5%” should be interpreted to include not only the explicitly recited values of about 0.1% to about 5%, but also include individual values (e.g., about 1%, about 2%, about 3%, and about 4%) and the sub-ranges (e.g., about 0.5% to about 1.1%; about 5% to about 2.4%; about 0.5% to about 3.2%, and about 0.5% to about 4.4%, and other possible sub-ranges) within the indicated range.

As used herein, “about,” “approximately,” “substantially,” and the like, when used in connection with a measurable variable such as a parameter, an amount, a temporal duration, and the like, are meant to encompass variations of and from the specified value including those within experimental error (which can be determined by e.g. given data set, art accepted standard, and/or with e.g. a given confidence interval (e.g. 90%, 95%, or more confidence interval from the mean), such as variations of +/−10% or less, +/−5% or less, +/−1% or less, and +/−0.1% or less of and from the specified value, insofar such variations are appropriate to perform in the disclosure. As used herein, the terms “about,” “approximate,” “at or about,” and “substantially” can mean that the amount or value in question can be the exact value or a value that provides equivalent results or effects as recited in the claims or taught herein. That is, it is understood that amounts, sizes, formulations, parameters, and other quantities and characteristics are not and need not be exact, but may be approximate and/or larger or smaller, as desired, reflecting tolerances, conversion factors, rounding off, measurement error and the like, and other factors known to those of skill in the art such that equivalent results or effects are obtained. In some circumstances, the value that provides equivalent results or effects cannot be reasonably determined. In general, an amount, size, formulation, parameter or other quantity or characteristic is “about,” “approximate,” or “at or about” whether or not expressly stated to be such. It is understood that where “about,” “approximate,” or “at or about” is used before a quantitative value, the parameter also includes the specific quantitative value itself, unless specifically stated otherwise.

The term “optional” or “optionally” means that the subsequent described event, circumstance or substituent may or may not occur, and that the description includes instances where the event or circumstance occurs and instances where it does not.

As used interchangeably herein, the terms “sufficient” and “effective,” can refer to an amount (e.g. mass, volume, dosage, concentration, and/or time period) needed to achieve one or more desired and/or stated result(s). For example, a therapeutically effective amount refers to an amount needed to achieve one or more therapeutic effects.

Various embodiments are described hereinafter. It should be noted that the specific embodiments are not intended as an exhaustive description or as a limitation to the broader aspects discussed herein. One aspect described in conjunction with a particular embodiment is not necessarily limited to that embodiment and can be practiced with any other embodiment(s). Reference throughout this specification to “one embodiment”, “an embodiment,” “an example embodiment,” means that a particular feature, structure or characteristic described in connection with the embodiment is included in at least one embodiment of the present disclosure. Thus, appearances of the phrases “in one embodiment,” “in an embodiment,” or “an example embodiment” in various places throughout this specification are not necessarily all referring to the same embodiment, but may. Furthermore, the particular features, structures or characteristics may be combined in any suitable manner, as would be apparent to a person skilled in the art from this disclosure, in one or more embodiments. Furthermore, while some embodiments described herein include some but not other features included in other embodiments, combinations of features of different embodiments are meant to be within the scope of the disclosure. For example, in the appended claims, any of the claimed embodiments can be used in any combination.

All patents, patent applications, published applications, and publications, databases, websites and other published materials cited herein are hereby incorporated by reference to the same extent as though each individual publication, published patent document, or patent application was specifically and individually indicated as being incorporated by reference.

This current disclosure describes a simple approach of using Al/Ga-polar growths and converting them to N-polar orientations using a substrate bonding and liftoff process to form a stacked configuration that may be varied in composition/structure. This disclosure hereby incorporates U.S. Provisional Patent Application 63/094,413 in its entirety.

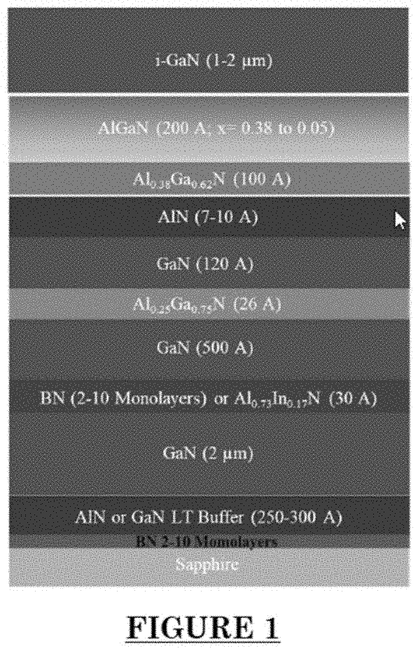

The current disclosure's approach consists of growing the N-polar device layers in reverse order over a Ga-Al-polar substrates or template followed by the laser liftoff of the Ga-polar substrate to have access to the N-polar face and then fabricating the device structure using standard lithography techniques. This procedure has been schematically outlined in FIGS. 1-6. This example is for fabricating a N-polar GaN-AlGaN HEMT, but the approach is universal and can be used for any other device type such as LEDs, detectors, modulators, lasers etc.

The N-polar device epilayers are grown on the sapphire (or any other UV transparent III-N epitaxy compatible substrate) or Si-substrate in reverse order. The structure may also contain at least one layer but possibly 2-10 monolayers of Boron Nitride (BN) layers, see FIG. 1.

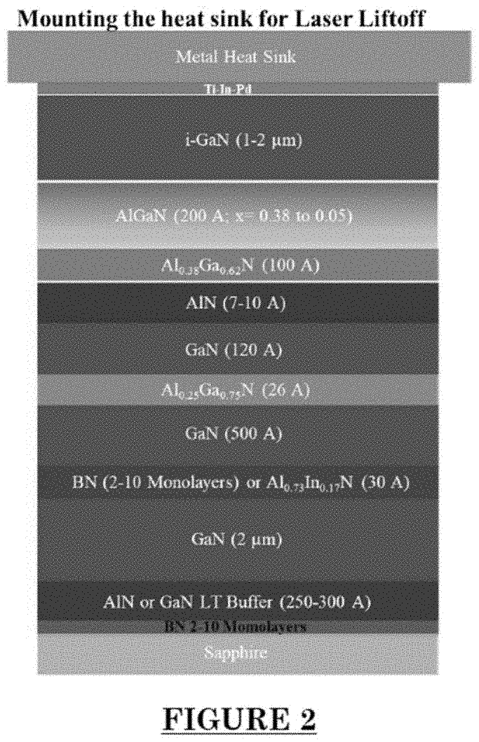

Now a metal heat sink is soldered to the very top Ga-face layer. The solder/epoxy material is selected to withstand the highest temperature that will be encountered in the subsequent processing, see FIG. 2. AlₓGa₁₋ₓN layers may also be incorporated as shown.

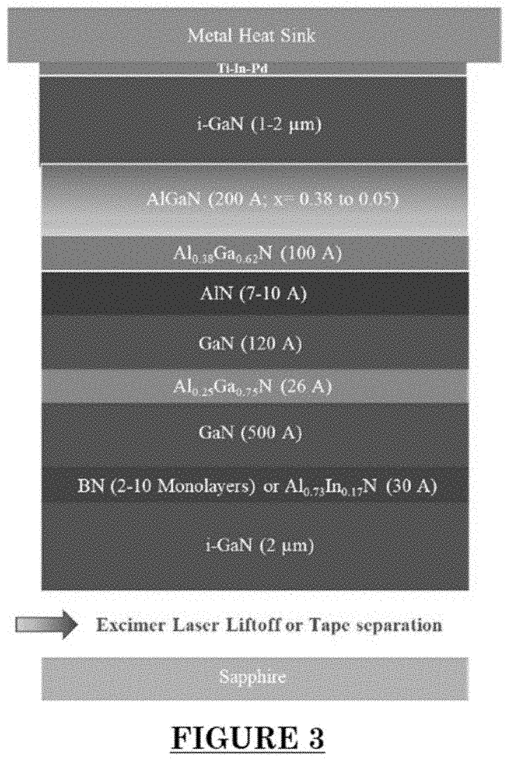

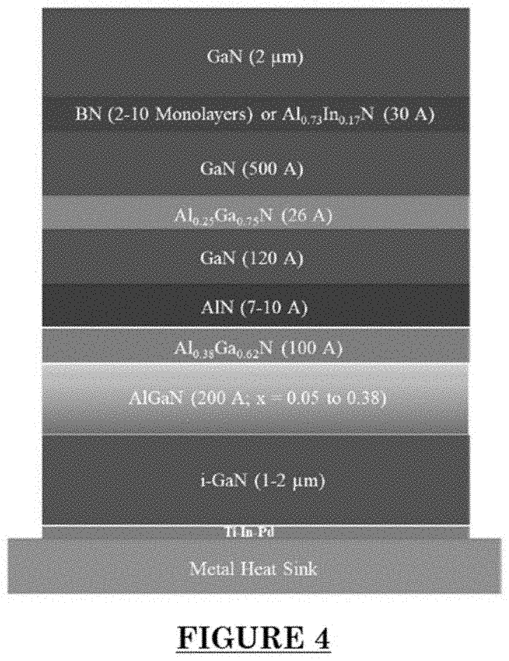

Next the substrate is separated from the structure of FIG. 2 by either laser liftoff or simple tape assisted separation (at BN layers), see FIG. 3. The metal heat sink assembly now acts as a substrate carrier for the epilayers as well when the whole structure is turned upside down, see FIG. 4.

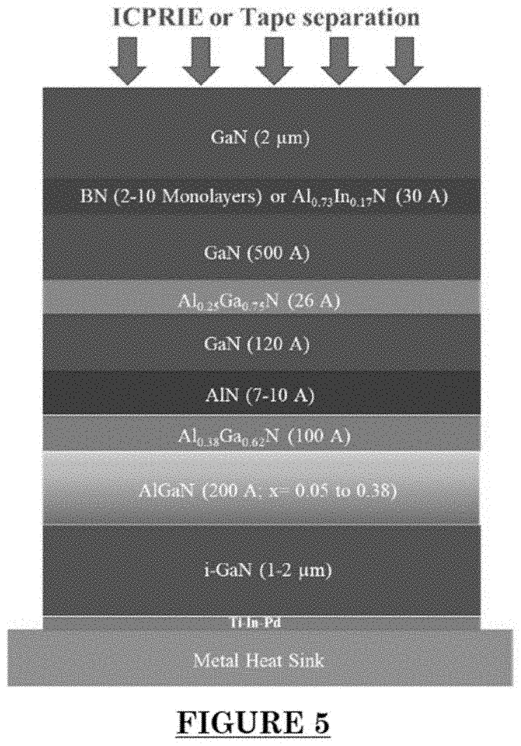

Now, since the N-polar face is exposed, the current disclosure uses standard lithography, metallization and reactive ion etching techniques to complete the device fabrication. The first processing step will be to etch the excess GaN layer to reach the remaining GaN cap layer (˜500 A). Note instead of RIE, a BN assisted liftoff approach can also be used, see FIG. 5. Also, to improve the RIE thickness control, we can bury a thin (˜30 A) AlₓInₓN layer in the GaN layer to server as an etch stop marker, see FIG. 5.

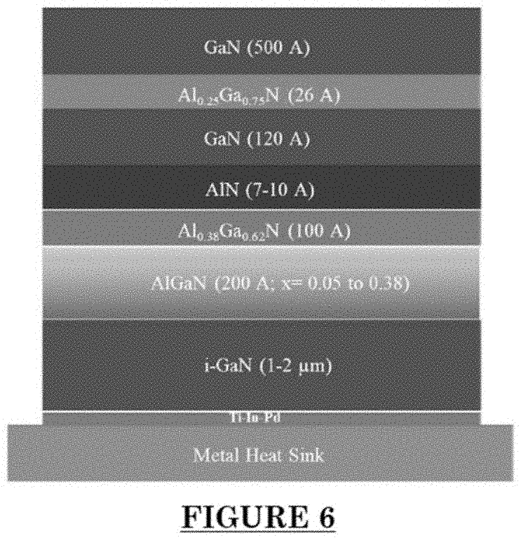

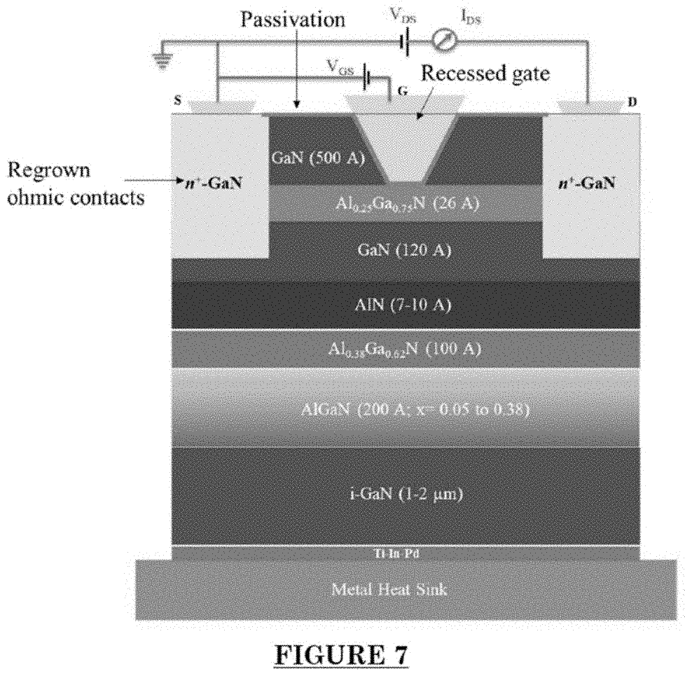

FIG. 6 shows the final N-polar epilayer stack that can now be used to fabricate the GaN—AlGaN HEMT which we have selected as an illustration of the approach. In FIG. 7, the final device configuration is included. To reach this we will need to do the source-drain ohmic contacts metallization and annealing, isolation MESA etching, gate-recess via reactive ion etching and then gate metallization, see FIG. 7. Note we can also include a field plate process to improve the device performance.

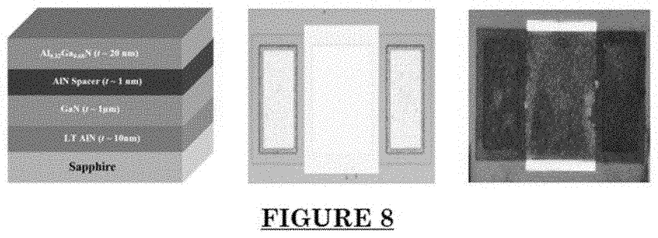

FIG. 8 shows at (a) The device structure of the AlGaN/GaN HEMT, Optical images of the HEMT (b) before and, (c) after laser lift-off. Demonstrated laser lift-off (LLO) of AlGaN/GaN HEMT's transistors onto another substrate, enabling an alternative pathway for the integration of DUV LED's with GaN electronics for photonic integrated circuits (PIC's).

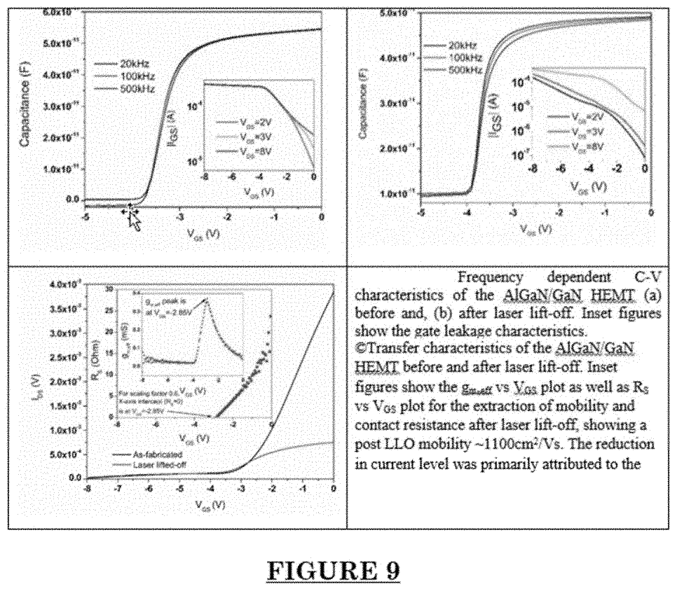

FIG. 9 shows frequency dependent C-V characteristics of the AlGaN/GaN HEMT at: (a) before and, (b) after laser lift-off. Inset figures show the gate leakage characteristics.

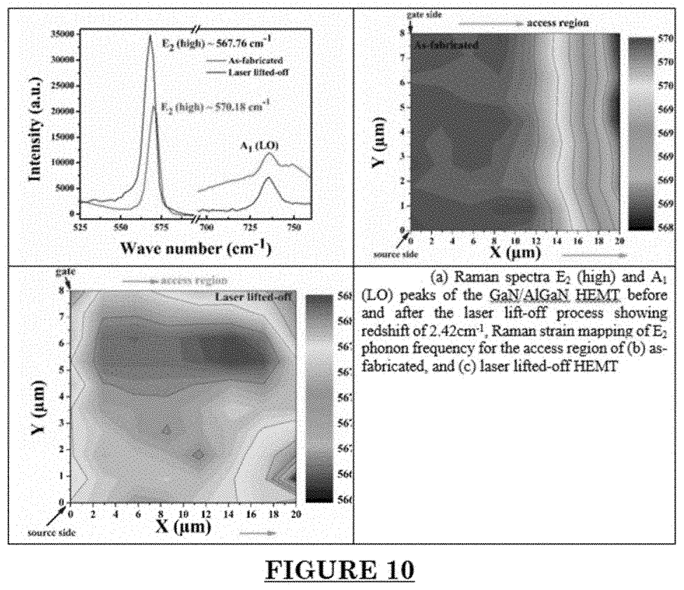

FIG. 10 shows at: (a) Raman spectra E2 (high) and A1 (LO) peaks of the GaN/AlGaN HEMT before and after the laser lift-off process showing redshift of 2.42 cm-1, Raman strain mapping of E2 phonon frequency for the access region of (b) as-fabricated, and (c) laser lifted-off HEMT

The goal here was to develop the ability to transfer a fabricated AlGaN/GaN high electron mobility transistor (HEMT) onto an arbitrary substrate using an excimer laser lift-off (LLO) process. This will enable the integration of the Ga-rich side of the AlGaN alloy system with the Al-rich side of the system (which the DUV LED's are a part of), by circumventing the challenges with in-situ crystal growth incompatibilities between GaN (˜900 C) and AlGaN (>1000 C). By transferring the device to a host substrate, after which the sapphire is removed, the N-polar side of the GaN HEMT is revealed, enabling ease of contact formation for subsequent integration with DUV LED's. FIG. 8 shows the transferred device, while FIG. 4 shows the electrical characteristics before and after LLO transfer. The threshold voltage was unchanged, whereas the current level decreased by 4×. Careful analysis of the transfer characteristics revealed this decrease to be due to a ˜30% reduction in carrier mobility, while the rest of the decrease is due to degradation of the ohmic contacts during transfer. We are currently developing a technique to form ohmic contacts after LLO transfer. Raman measurements in FIG. 10 show that a small amount of stress ˜1 GPa is relieved due to the transfer, although not enough to cause a significant change in the carrier concentrations measured in FIG. 9 at b by capacitance-voltage.

Thick AlN Template LLO as Heat Sinks for High Power Electronics.

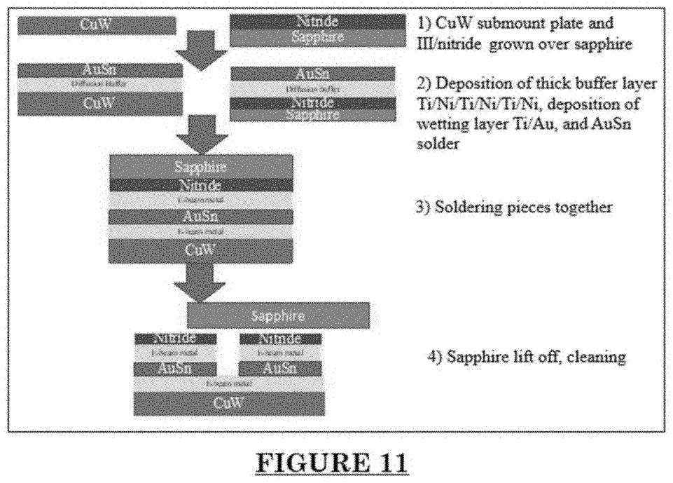

The first step involved development of thick ˜16 um thick AlN templates grown on sapphire using a novel growth technique enabling strain management for thick layers in a single growth process. We showed that these layers could be scaled to as thick as needed. If they are too thick, however, they are unsuitable as heat spreaders, as there will be too much series thermal resistance. Here, we demonstrate LLO transfer of this AlN heat spreader onto commercial submount packaging used in semiconductor packaging. The key steps are listed in FIG. 11, after which the LLO is performed through the back of the double side polished sapphire in step 4, see FIG. 11. This standalone AlN on metal packaging in now an ideal heat spreader in semiconductor power electronics for thermal management.

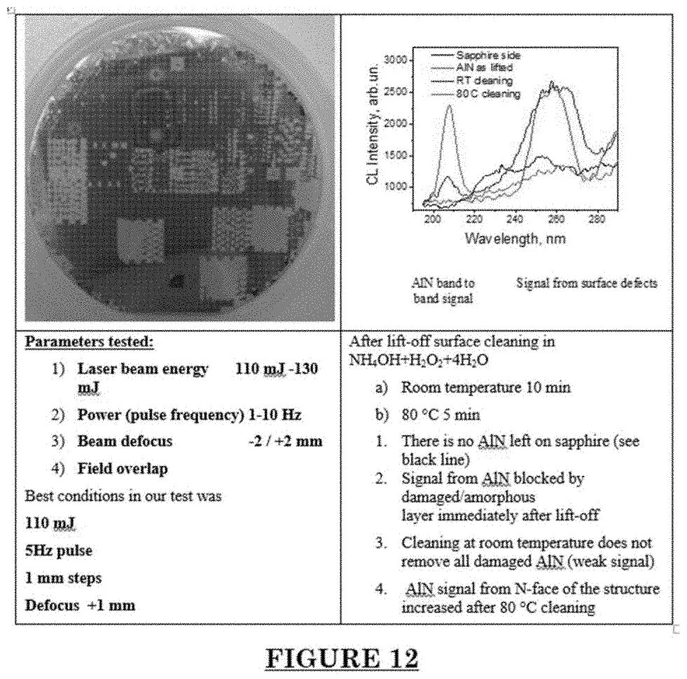

FIG. 12 shows an example of 1 mm blocks that have been transferred from the sapphire, and the characterization of their optoelectronic integrity using cathodoluminescence. Immediately after LLO transfer, the surface contains metallic and amorphous contamination that prevents the underlying bulk signal to be seen. After cleaning with ammonium hydroxide, this damage layer is removed, allowing the transferred layer to be clearly observed. Further optimization of the cleaning is likely needed, including acid cleans for metal removal, although this must be done in a manner not damaging to the metallic solders and submounts.

While the present subject matter has been described in detail with respect to specific exemplary embodiments and methods thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art using the teachings disclosed herein.

What is claimed is:

1. An improved method for forming N-polar device layers comprising:
forming at least one N-polar stacked configuration in reverse order via:
forming at least one N-polar epilayer over a UV transparent III-N epitaxy
compatible substrate;
forming at least one polar substrate;
forming at least one layer of boron nitride adjacent the substrate;
forming at least one heat sink as an uppermost layer of the stacked configuration;
separating the substrate and removing the at least one layer of boron nitride adjacent the substrate; and
inverting the stacked configuration to configure the at least one heat sink as a substrate carrier.

2. The method of claim 1, wherein the at least one polar substrate comprises Ga or Al.

3. The method of claim 1, wherein the UV transparent III-N epitaxy compatible substrate comprises sapphire.

4. The method of claim 1, wherein the UV transparent III-N epitaxy compatible substrate comprises silicon.

5. The method of claim 1, wherein from 2-10 layers of boron nitride are formed adjacent the substrate.

6. The method of claim 1, further comprising forming an N-polar epilayer stack as shown in FIG. 6.

7. The method of claim 1, further comprising forming at least one GaN layer between the substrate and heat sink.

8. The method of claim 1, further comprising forming at least one AlₓGa₁₋ₓN layer between the substrate and heat sink.

9. The method of claim 1, further comprising forming at least one AlₓInₓN layer between the substrate and heat sink to serve as an etch stop marker.

10. The method of claim 1, further comprising forming a second boron nitride layer between the substrate and heat sink.

11. The method of claim 10, further comprising removing the second boron nitride layer.

12. The method of claim 1, further comprising wherein separating the substrate and removing the at least one layer of boron nitride adjacent the substrate exposes an N-polar face of the stack configuration.

13. The method of claim 12, further comprising etching a GaN layer to reveal a GaN cap layer.

14. The method of claim 13, further comprising fabricating a GaN—AlGaN high electron mobility transistor from the configuration stack.

15. An improved method for forming N-polar device layers comprising:
forming at least one N-polar stacked configuration in reverse order via:
forming at least one N-polar epilayer over a UV transparent III-N epitaxy compatible substrate;
forming at least one layer of boron nitride adjacent the substrate;
forming at least one AlN or GaN buffer layer adjacent the at least one layer of boron nitride;
forming at least one heat sink as an uppermost layer of the stacked configuration;
forming at least one GaN layer between the substrate and heat sink;
separating the substrate and removing the at least one layer of boron nitride adjacent the substrate; and
inverting the stacked configuration to configure the at least one heat sink as a substrate carrier.

16. The method of claim 15, further comprising forming an N-polar epilayer stack as shown in FIG. 6.

17. The method of claim 15, further comprising forming at least one AlₓGa₁₋ₓN layer between the substrate and heat sink.

18. The method of claim 15, further comprising forming at least one AlₓInₓN layer between the substrate and heat sink to serve as an etch stop marker.

19. The method of claim 15, further comprising wherein separating the substrate and removing the at least one layer of boron nitride adjacent the substrate exposes an N-polar face of the stack configuration.
